(19) United States
(12) Patent Application Publication
(10) Pub. No.: US 2002/0127883 A1
(43) Pub. Date: Sep. 12, 2002

(54) Bis (tertiarybutylamino) silane and ozone based doped and undoped oxides

(76) Inventors: Richard A. Conti, Mount-Kisco, NY (US); Ashima B. Chakravarti, Hopewell Junction, NY (US); Kerem Kapkin, Watsonville, CA (US); Joseph C. Sisson, Watsonville, CA (US)

Correspondence Address: Philmore H. Colburn II, CANTOR COLBURN, 55 Griffin Road South, Bloomfield, CT, 06002, US

(21) Appl. No.: 09/756,937

(22) Filed: Jan. 9, 2001

(51) Int. Cl. H01L 21/31

(52) U.S. Cl. 438/787

(57) ABSTRACT

A CVD process for the deposition of silicon oxide by reacting BTBAS with an ozone reactant gas comprising providing a semiconductor wafer substrate in a single wafer reactor, contacting said substrate with a gaseous mixture containing a bis-tertiary butyl aminosilane reactant and an ozone reactant at a pressure ranging from about 10 Torr to about 760 Torr, and, heating said mixture at a temperature ranging from about 400 to about 600° C., whereby said reactants are reacted to deposit said oxide as a film on said substrate.

### BACKGROUND OF THE INVENTION

The present invention relates to a process of forming oxide films on a semiconductor substrate. In particular, the present invention relates to a CVD process for deposition of a doped or undoped oxide by reacting bis (tertiarybutlyamino) silane with an ozone reactant gas.

In the production of semiconductor wafers, it often is required to deposit a layer of a dielectric film on the substrate. Various techniques and source materials have been employed in the deposition of silicon dioxide layers. Undoped and doped silicon dioxide, for example, may be deposited employing low-pressure chemical vapor deposition (LPCVD) techniques using tetraethyl orthosilicate (TEOS) as the source material. Another commonly practiced technique for shallow trench isolation (STI) applications has been high-density plasma chemical vapor deposition (HDP CVD) techniques. However, such a process results in possible exposure to plasma charge damage. When utilized with a pre-metal dielectric (PMD) process, a two step routine including the deposition of a sub-atmospheric boro-phosphosilicate glass (SABPSG) is required, at the cost of decreased throughput.

Advances in processes for manufacture of semiconductor devices now permit millions of circuit elements, such as capacitors for dynamic memories and transistors for logic arrays, to be formed on a single chip. Many of these advances have been made possible through improvements in process control, since the conditions under which desired structures are formed may adversely affect previously formed structures.

For example, impurities may be located with substantial precision within a volume of semiconductor material by control of implantation processes and are generally diffused slightly during subsequent annealing at elevated temperature for a short period of time. Compensation for this diffusion can generally be made by the initial location of the implant so that the diffusion during carefully controlled heat treatment achieves the desired location of the impurities. The heat treatment also serves to repair damage to the crystal lattice structure caused by the implantation process by annealing.

However, further heat treatment subsequent to annealing may cause further diffusion which is not desired. Any such further diffusion becomes particularly critical as the sizes of structures forming electronic elements is reduced to obtain higher integration densities and high performance of transistors. Oxide growth may also occur at insulator interfaces through similar mechanisms of material diffusion. Accordingly, an aspect of integrated circuit design is referred to as a heat budget which must not be exceeded if fabrication of the integrated circuit device is to be successfully accomplished. Maximum temperatures are also imposed by some structures which cannot be exceeded after the structures are formed.

Integrated circuits including a large plurality of individual circuit elements also require those elements to be interconnected as well as connected to other structures (e.g. connection pads) for supplying power and input signals to the chip and extracting output signals from it. Such connections are generally made to overlie the circuit elements on the chip and therefore must be insulated therefrom except where connections are to be made.

The integrity and reliability of such connections may be comprised if the topology which the connections must traverse is severe. For these circuit elements, a silicate glass (SiO₂) is normally used as an insulator between metal line interconnections or in STI structures. In addition to conventional silicate glass, phosphorus is added as a dopant to provide alkali (Na, K, Li) gettering capability in the pre-metal dielectric (PMD) layer. Dopant concentrations of 2%-4% by weight of phosphorus are required to getter alkali elements. In the resulting phosphosilicate glass (PSG) layer, the addition of dopant also softens the silicate glass and provides an enhanced reflow characteristic under high temperature annealing conditions. Boron may also be added at concentrations of 4-6% by weight to further enhance the ability of the glass to reflow.

Accordingly, a common structure in the fabrication of integrated circuits is a so-called passivation layer, which is generally formed of a phosphosilicate glass film after electronic element structures are completed. To reduce severity of topology of the surface, it is necessary to fill surface discontinuities such as trenches or gaps between portions of a patterned layer without creating voids in the insulating layer which may cause shorts in metal layers deposited after the contact opening process.

Since trenches and gaps under current design rules may have a relatively high aspect ratio (e.g. 4:1 or greater ratio of depth to width) and be quite narrow (e.g. 0.2-0.1 micron or less), filling them is difficult. Failure to adequately fill such trenches and gaps is very likely to cause a major adverse impact on manufacturing yield either by creation of voids or failure to reduce severity of surface topology which compromises metal conductors. Voids are generally due to more rapid deposition at the top of a trench or gap than at the bottom, closing or restricting delivery of material to lower portions of the trench before it can be filled.

The insulator material must also be as dense as possible as deposited to provide a stable film that does not absorb atmospheric moisture. High film density thus avoids a post-deposition densification annealing step in forming the layer. High film density may also develop a high dielectric constant. However, as device spacings and film thicknesses are reduced, a high dielectric constant corresponding to suitable film density for good film stability may also increase capacitive coupling between conductors and becomes a source of noise susceptibility. Therefore, as will be discussed below, control of dielectric constant is becoming of increased importance in modem integrated circuit design.

To improve gap filling of fill material, silicate and phosphosilicate glass films are often deposited with boron doping (using a source such as triethylborate) to further reduce the viscosity of the glass so that these films can possibly flow (depending on temperature) both during deposition and/or during post-deposition annealing or thermal cycling. For STI applications, however, such doping is inappropriate due to the potential out-diffusion of boron to nearby device junctions. Where boron doping can be used, however, with moderate (4%-5% by weight) levels of boron doping, these films reflow after a thirty minute anneal at temperatures above 800°-850° C. and narrow gaps of aspect ratio in the range of 3:1-4:1 can be filled without voids. However, attempts to use a boron doping level in excess of 5% in combination with a 4%-5% phosphorus concentration are not successful due to instability of such highly doped films and defects that result therefrom.

Borophosphosilicate glass (BPSG) films may be deposited using tetraethylorthosilicate (TEOS), oxygen or ozone, a phosphorus source such as PH3, triethylphosphate (TEPO), triethylphosphite or trimethylphosphite and a boron source such as B₂H₆, trimethylborate, or triethylborate. Temperatures of either 400°-600° C. or 800°-850° C. have been used for the deposition. Although the higher temperature range provides some reflow during deposition, subsequent annealing at 800°-850° C. is still required to provide void-free gap fill at aspect ratios of 3:1-4:1.

However, the temperature and duration of this anneal/reflow process allows only a small process window or tolerance within the heat budget for some types of integrated circuits such as some dynamic random access memories (DRAMs) and is wholly incompatible with some CMOS devices and logic arrays which may be limited to temperatures below 650° C. Additionally, for some recent logic array designs and CMOS devices in particular, boron has been observed to be an unacceptable contaminant at the pre-metal dielectric (PMD) level due to its effect on gate oxide threshold voltage. Some variations in materials and thermal processing have been attempted to reduce the thermal cycle for producing a silicon dioxide or glass insulating layer but have only resulted in slight increase of the process window, at most, and, generally does not justify the increase in material cost and process complexity by significant improvement in manufacturing yield.

Multi-step plasma deposition/etch processes have also been developed to fill sub-half micron gaps up to aspect ratios of 1.5:1. In addition to the limited range of aspect ratio, these processes suffer from low throughput and foreign material contamination and risk of causing damage to underlying gate oxide due to plasma charging.

Similarly, reduction of the anneal temperature to 650° C. or less in accordance with the maximum temperatures for further processing of circuits including some types of CMOS devices has limited the aspect ratio at which void-free trench or gap filling can be achieved to about 1.5:1 regardless of dopant content. In general, the need to fill higher aspect ratio structures becomes more critical to meet the application of merged logic and DRAM on a single chip. In such an application, the minimum aspect ratio is at least 2:1. Accordingly, it is seen that known techniques and materials suitable for depositing an insulating layer over some CMOS logic devices are not suitable for dynamic memories and vice-versa although it is desirable to provide both such structures on a single chip. Additionally, modem and advanced CMOS integrated circuit designs include some narrow, high aspect ratio features which cannot be adequately filled by known processes.

Further, while addition of fluorine into BPSG may be effective to reduce viscosity somewhat and may also be desirable to reduce dielectric constant (e.g. to control parasitic capacitances, as alluded to above), little fluorine will be incorporated if the temperature during deposition is too high (above 750° C.). Thus the amount of incorporated fluorine will be small. For example, deposition at 750° C. or higher limits fluorine content to 0.1% or less. Therefore for many sources of fluorine such as fluoroethoxysilane (F-TEOS), deposition must be done at low temperatures which prevents high density from being developed in the as-deposited film and the low temperature deposition must be followed by a high temperature anneal/reflow process to achieve gap filling and increase density. Again, temperatures below 650° C. do not provide adequate gap filling of narrow or high aspect ratio gaps or trenches while higher temperatures are unsuitable for modern CMOS devices.

Many different methods of material deposition generally suitable for depositing silicon dioxide are known but fall short of providing a solution to high-aspect ratio gap-filling within necessary heat budgets and maximum temperatures. Many of these methods are also unattractive due to much reduced process productivity as a result of compromises required to achieve gap-fill. For example, in addition to the methods discussed above, plasma enhanced chemical vapor deposition (PECVD) has been extensively investigated for formation of passivation films. Gap-filling capability of a single step PECVD process (e.g. without reflow) is limited to about 1.5:1. Further, use of a plasma can cause charging of structures due to irregularities within the plasma which can damage electronic structures such as gates of field effect transistors.

PSG and BPSG films may be deposited in either thermal CVD (THCVD) or plasma enhanced CVD (PECVD) reactors. However, while either a THCVD or PECVD PSG or BPSG may be used to fill low aspect ratio (e.g. less than 1:1) features without voids, at higher aspect ratios the gap filling capabilities of PECVD and THCVD processes diverge dramatically due to fundamental differences in the natures of these processes.

In PECVD, reactants are ionized and dissociated in the gas phase by collisions with energetic electrons. The gas mixture presented to the wafer surface has many more species than in the case of THCVD due to the vigorous decomposition of the initial gas by high energy electron bombardment. As a result of the highly energetic gas phase species, species collide with the surface with near unit probability of sticking and reacting. Thus step coverage in PECVD is usually poor and closure is usually observed at the tops of gaps requiring filling while voids are left lower in the gaps.

In contrast, in THCVD, less energetic species have a lower probability of being deposited at the location of first collision with a surface and either lower or higher conformality than PECVD may result, depending on the species to be deposited and the deposition conditions. Additionally, less energetic gas phase reactions that may result in desirable intermediates crucial in achieving a particular result such as void-free gap fill may be produced which are not available from PECVD processes.

Furthermore, while THCVD may be practiced from mTorr pressures to atmospheric pressures (760 Torr) and above, PECVD is usually limited to a regime below 20 Torr due to the difficulty in maintaining a plasma at greater pressures. In addition, while similar reactant species may be used in both PECVD and THCVD systems, as a result of differences noted above, thin films deposited by PECVD have different stoichiometries, stress and stability. Therefore, results achievable with PECVD may not be achieved with THCVD and vice-versa.

Liquid phase deposition (LPD) such as depositing silicon dioxide or fluorinated silicon dioxide from a saturated solution of hydrofluorosilicic acid also develops a low density film. While this process can be conducted at even lower temperatures than PECVD, annealing is required to improve density of deposition for film stability. However, void-free gap filling of the as deposited film is limited to aspect ratios of about 1:1.

Multi-step deposition and etch back processes have been attempted using phosphorus doped TEOS and ozone SACVD at 600 Torr for developing interlevel dielectric fill at sub-quarter micron regimes. All of these multi-step deposition and etch back processes use reactive ion etching which subjects the substrate to potential device damage due to electrical charging. This damage is detrimental to advanced logic and DRAM devices where gate oxide thicknesses may be as low as 50 Angstroms or less. Furthermore, with such multi-step processes, the productivity of the process may be severely reduced due to either lowered deposition rate or the effect of interruption of the deposition process to introduce etching steps or transitions to different processing conditions.

Accordingly, as existing methods to fill high aspect gaps compromise process productivity and thereby increase processing cost to optimize gap fill, improvements to processing steps that can compensate for this reduced productivity are required.

### SUMMARY OF THE INVENTION

Now, according to the present invention, an improved process for deposition of an oxide film on a semiconductor substrate has been developed. The process comprises a CVD process for the deposition of silicon oxide by reacting bis (tertiarybutylamino) silane (BTBAS) with an ozone reactant gas.

By using BTBAS as the source material one can deposit doped or undoped silicate glass at low temperature with higher efficiency of chemical usage (maximizing deposition rate per unit chemical flow input to the reactor) without sacrificing film quality as measured by moisture content, wet etch rate, and stress.

Furthermore, in the presence of O_{3,} films can be derived having different carbon contents than can be achieved by the use of LPCVD due to the possible reaction of O₃ with any carbon containing intermediates that may be occluded in the deposited layer. The preferred overall lower reaction temperature of 400-600 ° C. utilized for the O₃/BTBAS reaction also may reduce the carbon content vs. that obtained with LPCVD. Carbon content of BTBAS/ozone based doped oxide films by SIMS analysis are reported to be in the range of 1E19, as compared to 1E20 for comparable LPCVD films.

### DESCRIPTION OF A PREFERRED EMBODIMENT OF THE INVENTION

According to the present invention, to form silicon dioxide films, the BTBAS source material and ozone (O₃) preferably are allowed to react in a single wafer CVD reactor at a temperature preferably ranging from about 400 to about 600° C., most preferably about 450° C. to about 500° C. The flow rate of the reactants preferably ranges from about 20 sccm to about 100 sccm. The ratio of O₃ to source material preferably ranges from about 2:1 to about 16:1; the ratio of O₂ to source material preferably ranges from about 50:1 to about 200:1. The reaction preferably is conducted under pressures ranging from about 10 to about 760 Torr; preferably about 200 to about 700 Torr. The reactants preferably are delivered to the reactor zone through a linear injector designed to maintain the separation of the reactants. Such a linear injector delivery system is, for example, shown in U.S. Pat. No. 5,944,900.

In an embodiment wherein a doped oxide fill is desired, a dopant is selected from the group consisting of As, B, P, and Ge. To add a dopant to the deposited oxide film, at the same time that the BTBAS is reacted with the ozone, a dopant precursor is introduced into the reaction zone. For example, precursors for phosphorus could be organic or inorganic in nature, such as, for example, PH₃, triethylphosphate (TEPO), trimethylphosphite (TMPi), trimethylphosphate (TMPO), and the like. The precursors for boron could likewise be organic or of inorganic nature and may be, for example, B₂H₆, triethylborate (TEB), trimethylborate (TMB), and the like. Possible inorganic and organic sources of As and Ge include AsH3, GeH4, tertiarybutyl arsine, tertiarybutyl germane, tetramethylorthogermanium (TMOGe), tetraethylorthogermanium (TEOGe), trimethyl arsine or trimethyl germane. The selection of the particular dopant source is determined by the required deposition rate and temperature consistent with both the deposition process and the thermal budget of the device. Other sources may be used as known by those skilled in the art. If it is desirable to introduce fluorine into the resultant film, a fluorine derivative of BTBAS may be included in the source material.

Table A below reports data from oxide dielectric films found by standard TEOS techniques as compared to oxides formed by reacting BTBAS in the presence of O₃ pursuant to the present invention. Reaction temperatures were 500° C.

TABLE A

| Response | TEOS | BTBAS |
|---|---|---|
| Moisture content at same | 2.62 | 1.87 |
| deposition rate of 2200 | | |
| A/min. (as deposited) | | |
| (wt % H₂O) | | |
| Stress (as deposited) | 160 | 145 |
| MPa | | |
| Stress (post anneal; | −205 | −215 |
| 1000c, 30′ N₂) MPa | | |
| Wet etch rate ratio (with | 14.85 | 14.66 |
| respect to thermal oxide, | | |
| as deposited) | | |

Table B below shows 500° C. deposition rate data comparing a TEOS undoped oxide with the BTBAS undoped oxide of the present invention.

TABLE B

| | Deposition Rate Efficiency |
|---|---|
| Precurser | (angstrom/min. Per sccm input) |
| BTBAS | 102.5 |
| TEOS | 75 |

Table C below compares a 500° C. TEOS doped oxide deposition with a BTBAS doped oxide deposition according to the present invention.

TABLE C

| Precursor | Deposition Rate Efficiency |
|---|---|
| BTBAS | 138 |
| TEOS | 107 |

While preferred embodiments have been shown and described, various modifications and substitutions maybe made thereto by one skilled in the art without departing from the spirit and scope of the invention. Accordingly, it is understood that the present invention has been described by way of illustration only, and such illustrations and embodiments as have been disclosed herein are not to be construed as limiting the scope of the claims.

We claim:

1. A method of forming an oxide film on a substrate, said method comprising:
a) providing a semiconductor wafer substrate in a single wafer reactor;
b) contacting said substrate with a gaseous mixture containing a bis-tertiary butyl aminosilane reactant and an ozone reactant at a pressure ranging from about 10 Torr to about 760 Torr; and,
c) heating said mixture at a temperature ranging from about 400 to about 600° C., whereby said reactants are reacted to deposit said oxide as a film on said substrate.

2. The method of claim 2 wherein said heating is at a temperature ranging from about 450 to about 500° C.

3. The method of claim 1 wherein said mixture further comprises a dopant precursor component and wherein said oxide deposited on said substrate contains a dopant resulting from said dopant precursor component.

4. The method of claim 3 wherein said dopant is selected from the group consisting of As, B, P, Ge, and the like.

5. The method of claim 4 wherein said dopant precursor component is a P dopant precursor selected from the group consisting of PH₃, TEPO, TMPi, TMPO, and the like.

6. The method of claim 4 wherein said dopant precursor is a B dopant precursor selected from the group consisting of B₂H₆, TEB, TMB, and the like.

7. The method of claim 4 wherein said dopant precursor is a As dopant precursor selected from the group consisting of AsH3, tertiarybutyl arsine, trimethyl arsine, and the like..

8. The method of claim 4 wherein said dopant precursor is a Ge dopant precursor selected from the group consisting of GeH₄, tertiarybutyl germane, tetramethylorthogermanium (TMOGe), tetraethylorthogermanium (TEOGe), trimethyl germane, and the like.

9. The process of claim 1 wherein said pressure ranges from about 200 to about 700 Torr.

10. The process of claim 1 wherein said gaseous mixture is delivered to said substrate using a linear injector.

11. The process of claim 1 wherein the flow rate of the reactants ranges from about 10 sccm to about 100 sccm.

12. A method of forming an oxide film on a substrate, said method comprising:
a) providing a semiconductor wafer substrate in a single wafer reactor;
b) contacting said substrate with a gaseous mixture containing a bis-tertiary butyl aminosilane reactant and an ozone reactant at a pressure ranging from about 10 Torr to about 760 Torr, wherein said gaseous mixture is delivered to saidsubstrate using a linear injector at a flow rate of reactants ranging from about 20 sccm to about 100 sccm.; and,
c) heating said mixture at a temperature ranging from about 400 to about 600° C., whereby said reactants are reacted to deposit said oxide as a film on said substrate.
